(19) United States
(12) Patent Application Publication
(10) Pub. No.: US 2015/0049322 A1
(43) Pub. Date: Feb. 19, 2015

(54) SUBSTRATE PROCESSING SYSTEM AND METHOD OF CONTROLLING THE SAME

(71) Applicant: SAMSUNG ELECTRONICS CO., LTD., Suwon-si (KR)

(72) Inventors: Sang-Hyuk PARK, Hwaseong-si (KR); Doo-Jin YUN, Suwon-si (KR); Chung-Jae LEE, Suwon-si (KR); In-Heui YUN, Hwaseong-si (KR); Chang-soo LEE, Yongin-si (KR)

(73) Assignee: SAMSUNG ELECTRONICS CO., LTD., Suwon-si (KR)

(21) Appl. No.: 14/320,695

(22) Filed: Jul. 1, 2014

(30) Foreign Application Priority Data
Aug. 19, 2013 (KR) 10-2013-0097571

(51) Int. Cl. G03F 7/20

(52) U.S. Cl. CPC G03F 7/70775
USPC 355/72

(57) ABSTRACT

A substrate processing system may include at least one transfer device which transfers a substrate between a plurality of substrate processors and includes a first controller which controls the transfer device and a first communication module connected to the first controller, and at least one maintenance device configured to perform maintenance for the substrate processors and includes a second controller which controls the maintenance device and a second communication module connected to the second controller. The first controller may obtain information about the maintenance device through the first and second communication modules to control the transfer device, and the second controller may obtain information about the transfer device through the first and second communication modules to control the maintenance device.

### CROSS-REFERENCE TO RELATED APPLICATIONS

This application claims priority from Korean Patent Application No. 10-2013-0097571, filed on Aug. 19, 2013, in the Korean Intellectual Property Office (KIPO), the contents of which are herein incorporated by reference in their entirety.

### BACKGROUND

1. Field

Apparatuses and methods consistent with exemplary embodiments relate to a substrate processing system and a method of controlling the substrate processing system. More particularly, apparatuses and methods consistent with exemplary embodiments relate to a substrate processing system including a plurality of substrate process devices and a method of controlling the substrate processing system.

2. Description of the Related Art

In a semiconductor device or a flat panel display device manufacturing system, a transfer device may be used to transfer a substrate such as a semiconductor wafer or a flat display substrate between manufacturing devices which perform individual processes. For example, the transfer device may include an overhead hoist transport (OHT) which uses a rail to transfer a substrate over manufacturing devices in a clean room. Further, a crane located at a maintenance device may be used for maintaining or setting up manufacturing devices.

However, when different devices such as a transfer device and a maintenance device operate in the same workspace, accidents may occur due to the interference between the different devices.

### SUMMARY

One or more exemplary embodiments provide a substrate processing system capable of preventing accidents due to the interference between different devices of the substrate processing system.

According to an aspect of an exemplary embodiment, a substrate processing system may include a transfer device configured to transfer a substrate between a plurality of substrate processors, the transfer device including a first controller which controls the transfer device, and a first communication module connected to the first controller; and a maintenance device configured to perform maintenance for the substrate processors, the maintenance device including a second controller which controls the maintenance device, and a second communication module connected to the second controller, wherein the first controller controls the transfer device using information about the maintenance device obtained from the first and second communication modules, and the second controller controls the maintenance device using information about the transfer device obtained from the first and second communication modules.

The transfer device may include an overhead hoist transport (OHT).

The maintenance device may include a crane for maintenance or setup for the substrate processors.

A transfer device may travel along a first line and the maintenance device may travel along a second line independent of the first line.

The first line and the second line may be arranged adjacent to each other.

The substrate processing system may further include a first interface module configured to receive real time information between the transfer device and at least one of the substrate processors, and a second interface module connected to the second controller which communicates with the first interface module. The second controller may obtain real time information between the transfer device and at least one of the substrate processors through the first and second interface modules to control the maintenance operation.

The first interface module may be installed in each of the substrate processors.

The first interface module may receive and transmit an optical signal between the transfer device and the substrate processors.

The transfer device may include a first optical communication interface, each of the substrate processors may include a second optical communication interface, and the first and second optical communication interfaces may receive and transmit an optical signal as a control signal between the transfer device and each of the substrate processors.

The substrate processing system may perform a photolithography process using the substrate processors.

According to an exemplary embodiment, in a method of controlling a substrate processing system, the substrate processing system may include a transfer device configured to transfer a substrate between a plurality of substrate processors and a maintenance device configured to perform maintenance for the substrate processors, first and second communication modules are connected to the transfer device and the maintenance device respectively. Information about at least one of the transfer device or the maintenance device may be obtained from the first and second communication modules. The transfer device or the maintenance device may be controlled to avoid interference between the transfer device and the maintenance device based on the obtained information.

In an exemplary embodiment, controlling at least one of the transfer device or the maintenance device may include discontinuing an operation of the maintenance device on the substrate processor when the transfer device operates on the substrate processor, or discontinuing an operation of the transfer device on the substrate processor when the maintenance device operates on the substrate processor.

The method may further include obtaining information between the transfer device and each of the substrate process devices.

Obtaining information between the transfer device and each of the substrate processors may include receiving and transmitting an optical signal between the transfer device and each of the substrate processors using first and second optical communication interfaces.

The substrate processing system may perform a photolithography process using the substrate processors.

A first controller controlling a transfer device and a second controller controlling a maintenance device may exchange state information between the transfer device and the maintenance device to control the transfer device or the maintenance device.

A substrate processing method according to an exemplary embodiment may include transferring a substrate between a plurality of substrate processors, obtaining position information of at least one of a transfer device and a maintenance device using a first module connected to the transfer device and a second module connected to the maintenance device, detecting an interference condition between the transfer device and the maintenance device using the obtained position information, adjusting an operation of at least one of the transfer device and the maintenance device when an interference condition is detected, and processing a substrate according to the adjusted operation

The position information may be communicated between the first and second modules.

The position information may be obtained from at least one of the substrate processors.

The transferring may be performed by an overhead hoist transport (OHT).

The adjusting may include modifying at least one of movement of the transfer device along a first line and movement of the maintenance device along a second line independent of the first line.

Accordingly, a substrate processing system may exchange information between different devices of the transfer device and the maintenance device to perform control in a common workspace. Through the information communications between different devices, the substrate processing system may be controlled and operated efficiently in the same time and space without accidents.

### BRIEF DESCRIPTION OF THE DRAWINGS

Various aspects of exemplary embodiments will be more clearly understood from the following detailed description taken in conjunction with the accompanying drawings, in which:

FIG. 1 is a perspective view illustrating a substrate processing system in accordance with an exemplary embodiment.

FIG. 2 is a plan view illustrating the substrate processing system in FIG. 1.

FIG. 3 is a block diagram illustrating the substrate processing system in FIG. 1.

FIG. 4 is a flow chart illustrating a method of controlling a substrate processing system in accordance with an exemplary embodiment.

FIG. 5 is a block diagram illustrating a substrate processing system in accordance with an exemplary embodiment.

FIG. 6 is a block diagram illustrating an interface module between a substrate process device and a transfer device in FIG. 5.

FIG. 7 is a flow chart illustrating a method of controlling a substrate processing system in accordance with an exemplary embodiment.

FIG. 8 is a block diagram illustrating a substrate processing system in accordance with an exemplary embodiment.

### DETAILED DESCRIPTION OF EXEMPLARY EMBODIMENTS

Various exemplary embodiments will be described more fully hereinafter with reference to the accompanying drawings, in which various aspects of exemplary embodiments are shown. Exemplary embodiments may, however, be embodied in many different forms and should not be construed as limited to exemplary embodiments set forth herein. Rather, these exemplary embodiments are provided so that this disclosure will be thorough and complete, and will fully convey the scope of various aspects of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (e.g., rotated 90 degrees or at other orientations) and the spatially relative descriptors used herein interpreted accordingly.

The terminology used herein is for the purpose of describing various aspects of particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as being limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which the exemplary embodiments relate. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, various aspects of exemplary embodiments will be more fully described, with reference to the accompanying drawings.

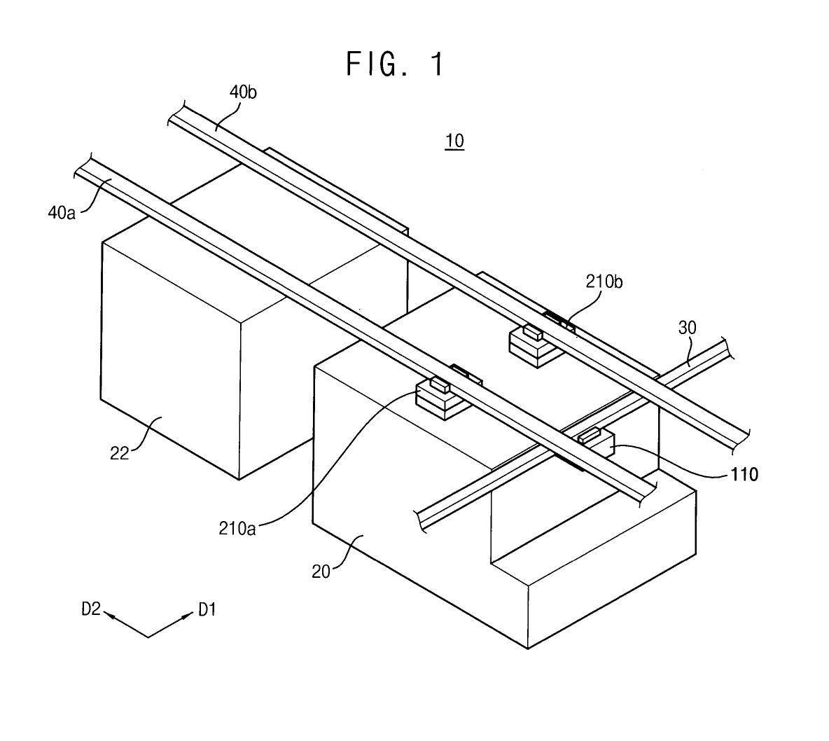

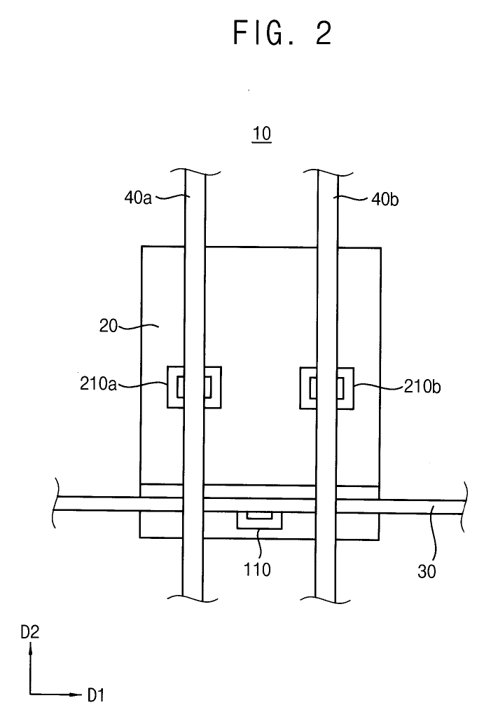

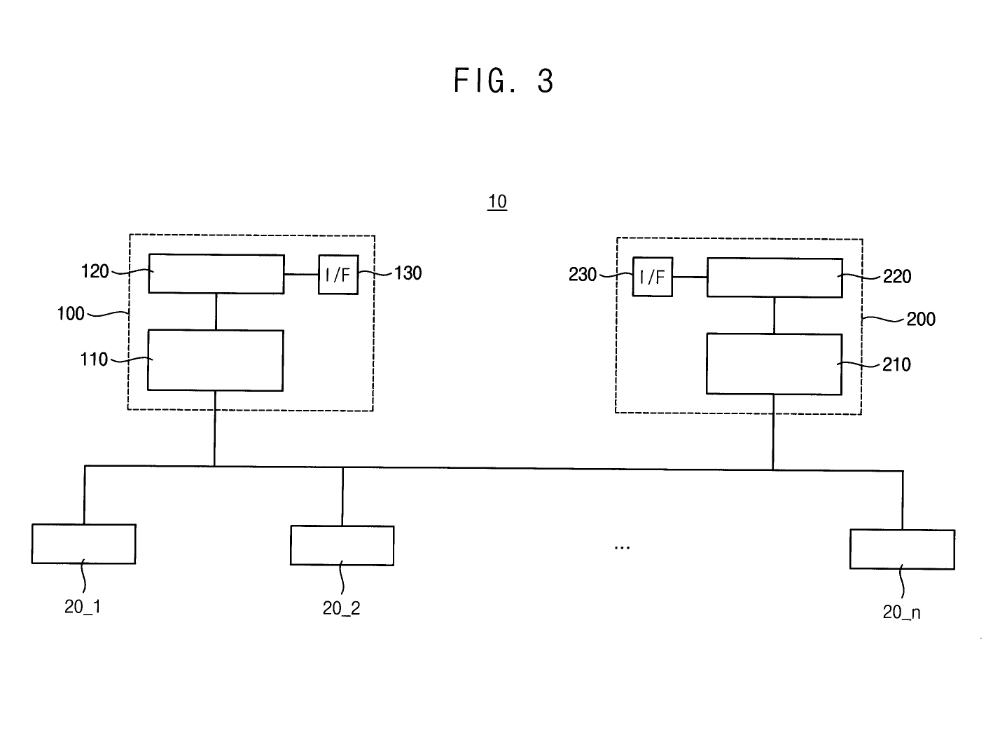

FIG. 1 is a perspective view illustrating a substrate processing system in accordance with an exemplary embodiment. FIG. 2 is a plan view illustrating a substrate processing system of FIG. 1. FIG. 3 is a block diagram illustrating a substrate processing system of FIG. 1.

Referring to FIGS. 1 to 3, a substrate processing system 10 may include a plurality of substrate process devices 20 and 22 (e.g., substrate processors that process a substrate), at least one transfer device 100 configured to transfer a substrate between the substrate process devices 20 and 22, and at least one maintenance device 200 configured to perform maintenance for the substrate process devices 20 and 22.

In an exemplary embodiment, the substrate processing system 10 may include a plurality of substrate process devices 20 and 22 for performing a photolithography process, an etching process, or the like. The substrate process devices 20 and 22 may be arranged sequentially in a first direction (D1) or a second direction (D2) perpendicular to the first direction (D1), with respect to each other.

For example, the substrate process devices 20 and 22 of the substrate processing system 10 may include, for example, a coating process device, an exposure process device, etc. The coating process device and exposure process device may be arranged sequentially in the second direction (D2) in a cleaning room.

The coating process device 20 may include a plurality of elements such as a carrier station element, a process element, an interface element, or the like. A carrier station element may be provided for loading and unloading a carrier (e.g., a Front Opening Unified Pod (FOUP)) which receives a plurality of wafers therein. Substrate process device 20 may comprise an exposure process device including an exposure apparatus for performing EUV lithography process.

Alternatively, the substrate processing system 10 may include substrate process devices 20 and 22 for performing a photolithography process on a glass substrate of a flat panel display (FPD).

As illustrated in FIGS. 1 and 2, the transfer device 100 may transfer an object to be processed, such as a substrate between the substrate process devices 20 and 22. The transfer device 100 may include an overhead hoist transport (OHT) 110 which travels along a first line 30 above the substrate process devices 20 and 22. A plurality of transfer devices 100 may be provided to transfer an object.

For example, the OHT 110 may move along the first line 30 in the first direction (D1) to transfer the carrier to a carrier station element. Alternatively, the OHT 110 may transfer a reticle to a substrate process device 20 or 22 for a EUV lithography process.

The maintenance device 200 may perform maintenance or setup for a substrate process device 20 or 22. In one exemplary embodiment, maintenance device 200 may include a crane 210 which travels along a second line 40a, 40b installed above substrate process devices 20 and 22.

For example, the crane 210 may move along the second line 40a, 40b to repair or set up for a coating process device. A pair of crane modules 210a and 210b may cooperatively move a part of a coating process device upward or downward for maintenance or setting up a coating process device.

In an exemplary embodiment, the OHT 110 of the transfer device 100 may travel along the first line 30, whereas the crane 210 of the maintenance device 200 may travel along the second line 40a, 40b independent of the first line 30.

As illustrated in FIG. 2, the first line 30 and the second line 40a, 40b may be arranged adjacent to each other in a common workspace (for example, a coating process area). As shown by FIG. 2, the first line 30 and the second line 40a, 40b may overlap in the common workspace. Accordingly, the transfer device 100 and the maintenance device 200 may be operated simultaneously in the common workspace.

As illustrated in FIG. 3, the transfer device 100 may include a first controller 120 and a first interlock communication module 130 (e.g., first communication module). The first controller 120 may be connected to the OHT 110 and control an operation of the OHT 110. The first interlock communication module 130 may be connected to the first controller 120 and communicate with an external communication module. The first controller 120 may be connected to a host computer to control specific operations of the OHT 110 according to transfer operation instructions.

The maintenance device 200 may include a second controller 220 and a second interlock communication module 230 (e.g., second communication module). The second controller 220 may be connected to the crane 210 and control an operation of the crane 210. The second interlock communication module 230 may be connected to the second controller 220 and communicate with an external communication module. The second controller 220 may be connected to a host computer (not illustrated) to control specific operations of the crane 210 according to maintenance operation instructions.

The first interlock communication module 130 and the second interlock communication module 230 may communicate with each other using a predetermined protocol. For example, the first interlock communication module 130 and the second interlock communication module 230 may transmit and receive signals therebetween by, for example, Ethernet®, or the like.

The first controller 120 and the second controller 220 may receive and provide information between the transfer device 100 and the maintenance device 200 through the first and second communication modules 130 and 230. The first controller 120 may receive information about the crane 210 of the maintenance device 200 through the first and second communication modules 130 and 230. The second controller 220 may receive information about the OHT 110 of the transfer device 100 through the first and second communication modules 130 and 230.

Accordingly, the first controller 120 may obtain position information corresponding to the maintenance device 200 through the first and second communication modules 130 and 230 to control a transfer operation. The second controller 220 may obtain position information of the transfer device 100 through the first and second communication modules 130 and 230 to control a maintenance operation.

For example, when the first controller 120 controls the OHT 110 of the transfer device 100 to transfer a substrate to a first substrate process device 20_1 of first to nth substrate process devices 20_1, 20_2, . . . , 20_{—}n, a control signal of the first controller 120 may be transmitted to the second controller 220 through the first and second communication modules 130 and 230. Then, the second controller 220 may generate a control signal to stop a coincidental maintenance operation of the crane 210 for the first substrate process device 20_1 in order to avoid interference between the transfer device 100 and the maintenance device 200.

When the second controller 220 controls the crane 210 of the maintenance device 200 to perform maintenance for a first substrate process device 20_1 of the first to n^{th} substrate process devices 20_1, 20_2, . . . , 20_{—}n, a control signal of the second controller 220 may be transmitted to the first controller 120 through the first and second communication modules 130 and 230. Then, the first controller 120 may generate a control signal to stop a coincidental transfer operation of the OHT 110 to the first substrate process device 20_1 in order to avoid interference between the transfer device 100 and the maintenance device 200.

Accordingly, the substrate processing system 10 may communicate information between the transfer device 100 and the maintenance device 200 to provide control in a common workspace. Through the information communications between different devices, the substrate processing system 10 may be controlled and operated efficiently in the same time and space without accidents.

Hereinafter, a method of controlling the substrate processing system in FIG. 1 will be explained.

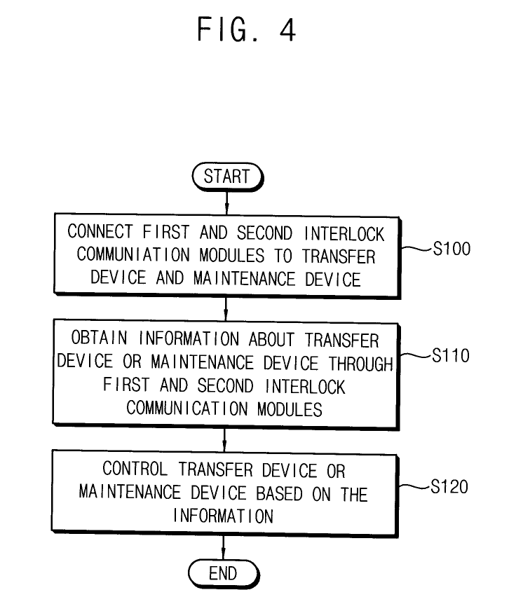

FIG. 4 is a flow chart illustrating a method of controlling a substrate processing system in accordance various aspects of exemplary embodiments. The substrate processing system 10 may, for example, be used to perform a photolithography process on a wafer, although it may not be limited thereto.

Referring to FIGS. 1 to 4, a substrate processing system 10 may include a transfer device 100 configured to perform a transfer operation between a plurality of substrate process devices and a maintenance device configured to perform maintenance for the substrate process devices 20 and 22.

The substrate process devices 20 and 22 may be arranged sequentially in a first direction (D2) or in a second direction (D2) perpendicular to the first direction (D1). For example, the substrate process device 10 may include a coating process device as a substrate process device 20, an exposure process device as a substrate process device 22, or the like for performing a photolithography process.

The transfer device 100 may include an overhead hoist transport (OHT) 110 which travels along a first line 30 installed above the substrate process devices 20 and 22. The transfer device 100 may also include a first controller 120 which controls the OHT 110. The maintenance device 200 may include a crane 210 which travels along a second line 40a, 40b installed above substrate process devices 20 and 22. Maintenance device 200 may also include a second controller 220 which controls the crane 210.

The first line 30 and the second line 40a, 40b may be arranged adjacent to each other in a common workspace (for example, a coating process area). As seen in FIG. 2, the first line 30 and the second line 40a, 40b may overlap each other in the common workspace.

First and second interlock communication modules 130 and 230 may communicate with each other and be connected to the transfer device 100 and the maintenance device 200 respectively (S100).

In particular, the first interlock communication module 130 may be connected to a first controller 120 of the transfer device 100 and may communicate with an external communication module. The second interlock communication module 230 may be connected to a second controller 220 of the maintenance device 200 and may communicate with an external communication module. The first interlock communication module 130 and the second interlock communication module 230 may communicate with each other using a predetermined protocol. For example, the first interlock communication module 130 and the second interlock communication module 230 may transmit and receive signals therebetween by, for example, Ethernet® or the like.

Then, information about the transfer device 100 or the maintenance device 200 may be obtained using the first and second interlock communication modules 130 and 230 (S110).

The first controller 120 and the second controller 220 may receive and transmit information between the transfer device 100 and the maintenance device 200 through the first and second communication modules 130 and 230. The first controller 120 may receive information about the crane 210 of the maintenance device 200 using the first and second communication modules 130 and 230. The second controller 220 may receive information about the OHT 110 of the transfer device 100 using the first and second communication modules 130 and 230.

The information about the transfer device 100 may include a control signal of the first controller 120 which controls the OHT 110. For example, the control signal of the first controller 120 may represent information of a substrate process device 20 or 22 to be selected for loading/unloading, a position of the OHT 110, etc. The information about the maintenance device 200 may be a control signal of the second controller 220 which controls the crane 210. For example, the control signal of the second controller 220 may represent information of a substrate process device 20 or 22 to be selected for maintenance or setup, the position of the crane 210, or the like.

Then, an operation of the transfer device 100 or the maintenance device 200 may be controlled based on the received information (S 120).

The first controller 120 may obtain position information corresponding to the maintenance device 200 using the first and second communication modules 130 and 230 to control the transfer operation. The second controller 220 may obtain position information corresponding to the transfer device 100 through the first and second communication modules 130 and 230 to control the maintenance operation.

For example, when the first controller 120 controls the OHT 110 of the transfer device 100 to transfer a substrate to a first substrate process device 20_1 of first to nth substrate process devices 20_1, 20_2, . . . , 20_{—}n, a control signal of the first controller 120 may be transmitted to the second controller 220 using the first and second communication modules 130 and 230. Then, the second controller 220 may generate a control signal to stop a coincidental maintenance operation of the crane 210 for the first substrate process device 20_1 in order to avoid interference between the transfer device 100 and the maintenance device 200.

When the second controller 220 controls the crane 210 of the maintenance device 200 to perform maintenance for a first substrate process device 20_1 of the first to n^{th} substrate process devices 20_1, 20_2, . . . , 20_{—}n, a control signal of the second controller 220 may be transmitted to the first controller 120 using the first and second communication modules 130 and 230. Then, the first controller 120 may generate a control signal to stop a coincidental transfer operation of the OHT 110 to the first substrate process device 20_1 in order to avoid interference between the transfer device 100 and the maintenance device 200.

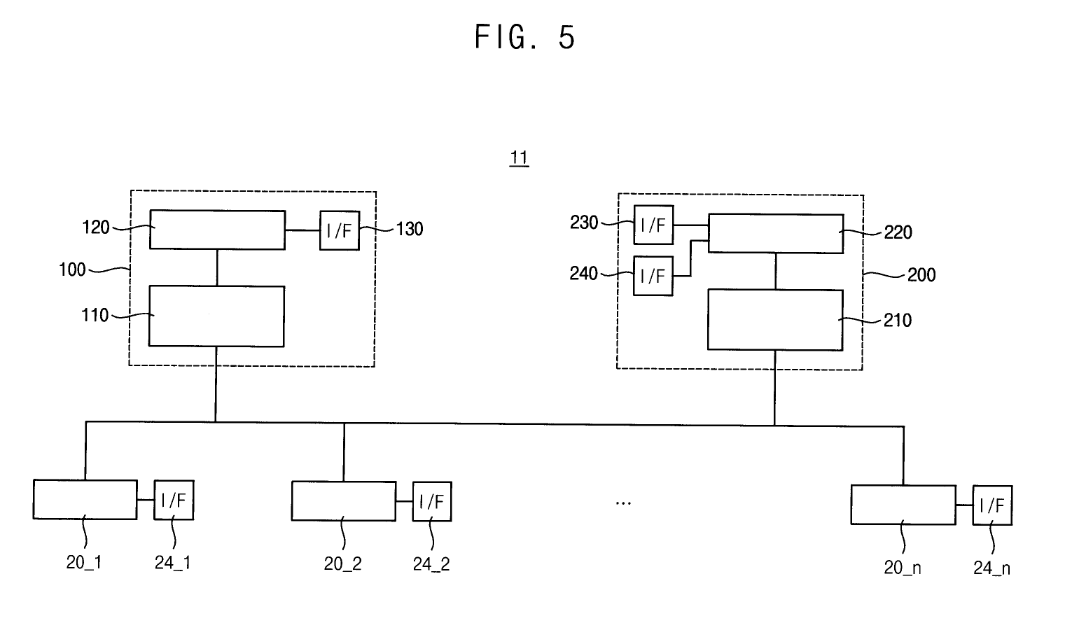

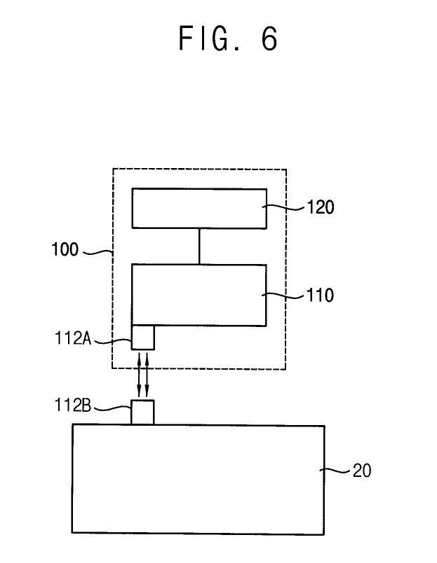

FIG. 5 is a block diagram illustrating a substrate processing system in accordance with an exemplary embodiment. FIG. 6 is a block diagram illustrating an interface between a substrate process device and a transfer device in FIG. 5. The substrate processing system may be substantially the same as the substrate processing system described with reference to FIGS. 1 to 3 except for an additional interface module. Thus, like reference numerals refer to like elements, and detailed descriptions thereon are omitted herein.

Referring to FIGS. 5 and 6, a substrate processing system 11 may further include first interface modules 24_1, 24_2, . . . , 24_{—}n and a second interface module 240 as a communication module between a transfer device 100 and a maintenance device 200.

The first interface module 24 may receive real time information between the transfer device 100 and each of the substrate process devices 20_1, 20_2, . . . , 20_{—}n and communicate with an external module. The second interface module 240 may be connected to a second controller 220 and communicate with the first interface modules 24_1, 24_2, . . . , 24_{—}n. The second controller 220 may obtain real time information between the transfer device 100 and substrate process devices 20 and 22 through the first interface modules 24_1, 24_2, . . . , 24_{—}n and second interface modules 240 to control a maintenance operation.

A first interface module 24 may be installed in each of the substrate process devices 20_1, 20_2, . . . , 20_{—}n. Alternatively, a first interface module 24 may be installed in an OHT 110 of the transfer device 100. The first interface modules 24_1, 24_2, . . . , 24_{—}n may receive and transmit an optical signal between the OHT 110 of the transfer device 100 and the substrate process devices 20 and 22.

As illustrated in FIG. 6, the transfer device 100 may include a first optical communication interface 112A installed in the OHT 110 and each substrate process device 20 may include a second optical communication interface 112B. The first and second optical communication interfaces 112A and 112B may be optically coupled parallel input/output (I/O) communication interfaces based on SEMI standard E84.

The first and second optical communication interfaces 112A and 112B may receive and transmit an optical signal as a control signal between the OHT 110 of the transfer device 100 and each substrate process device 20. That is, the first and second optical communication interfaces 112A and 112B may receive and transmit an optical signal as a control signal to perform loading or unloading of a carrier between the transfer device 100 and a substrate process device 20.

For example, the transfer device 100 and a substrate process device 20 may receive and transmit a load requirement signal, an unload requirement signal, a work processing signal (busy signal), or the like, through the first and second optical communication interfaces 112A and 112B, to perform a transfer operation to a substrate process device 20.

A first interface module 24 may be connected to the first and second optical communication interfaces 112A and 112B to receive signals between the first and second optical communication interfaces 112A and 112B. Accordingly, a first interface module 24 may receive and process an optical signal representing real time information between the OHT 110 of the transfer device 100 and a substrate process device 20, and transmit the processed optical signal. The second interface module may receive the processed optical signal from a first interface module 24 and provide the processed optical signal to the second controller 220.

As illustrated in FIG. 5, for example, when the OHT 110 of the transfer device 100 transfers a substrate to a first substrate process device 20_1, a busy signal may be transmitted between the first and second optical communication interfaces 112A and 112B. The first interface module 24_1 may obtain the busy signal between the first and second optical communication interfaces 112A and 112B and transmit the busy signal to the second interface module 240. Then, the second controller 220 may generate a control signal using the obtained real time information between the transfer device 100 and the first substrate process device 20_1 to stop a coincidental maintenance operation of the maintenance device 200.

In this exemplary embodiment, real time position information between the transfer device 100 and each of the substrate process devices 20 and 22 may be obtained and used to control the maintenance device 200. Alternatively, although it is not illustrated in the figures, real time position information between the maintenance device 200 and each of the substrate process devices 20 and 22 may be obtained and used to control the transfer device 100.

Hereinafter, a method of controlling the substrate processing system 11 in FIG. 5 will be explained.

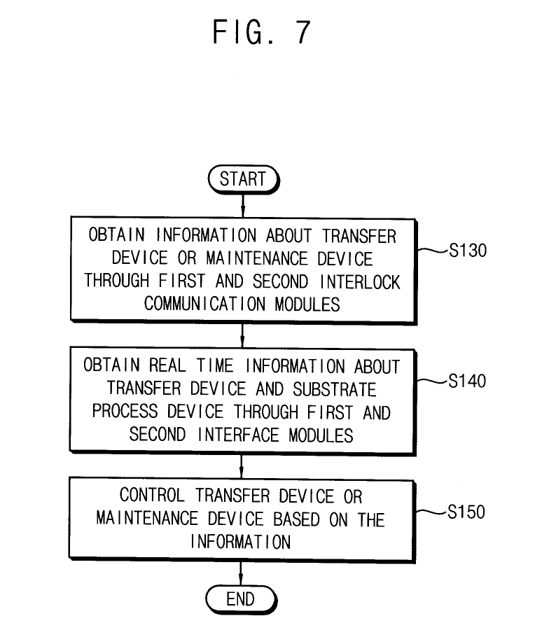

FIG. 7 is a flow chart illustrating a method of controlling a substrate processing system 10, 11 in accordance with exemplary embodiments.

Referring to FIG. 7, the steps S100 and S110 described with reference to FIG. 4 may be performed to obtain information about the transfer device 100 or the maintenance device 200 through first and second interlock communication modules 130 and 230 (S130).

The first controller 120 and the second controller 220 may receive and provide information between the transfer device 100 and the maintenance device 200 using the first and second communication modules 130 and 230. The first controller 120 may receive information about a crane 210 of the maintenance device 200 using the first and second communication modules 130 and 230. The second controller 220 may receive information about an OHT 110 of the transfer device 100 using the first and second communication modules 130 and 230.

The information about the transfer device 100 may be a control signal for the first controller 120 which controls the OHT 110. For example, a control signal of the first controller 120 may represent information about a substrate process device 20 or 22 to be selected for loading/unloading, a position of the OHT 110, or the like. The information about the maintenance device 200 may be a control signal for the second controller 220 which controls the crane 210. For example, the control signal of the second controller 220 may represent information about a substrate process device 20 or 22 to be selected for maintenance or setup, a position of the crane 210, or the like.

Then, real time information between the transfer device 100 and the maintenance device 200 may be obtained through first and second interface modules (S 140).

As illustrated in FIG. 5, a first interface module may be installed in each of the substrate process devices 20_1, 20_2, . . . , 20_{—}n. Alternatively, a first interface module 24 may be installed in the OHT 110 of the transfer device 100. The first interface module 24 may receive and transmit an optical signal between the OHT 110 of the transfer device 100 and a substrate process device. The second interface module 240 may be connected to a second controller 220 and may communicate with the first interface module 24.

As illustrated in FIGS. 5 and 6, for example, when the OHT 110 of the transfer device 100 transfers a substrate to a first substrate process device 20_1, a busy signal may be transmitted between first and second optical communication interfaces 112A and 112B. A first interface module 24_1 may obtain the busy signal between the first and second optical communication interfaces 112A and 112B and transmit the busy signal to the second interface module 240.

Then, the transfer device 100 or the maintenance device 200 may be controlled based on the obtained information (S 150).

The second controller 220 may obtain information about the transfer device 100 using a control signal from the first controller 120 which is used to control the maintenance device 200. The first controller 120 may obtain information about the maintenance device 200 using a control signal from the second controller 220 which is used to control the transfer device 100.

The second controller 220 may obtain real time information between the transfer device 100 and each of the substrate process devices 20_1, 20_2, . . . , 20_{—}n which is used to control the maintenance device 200. Alternatively, although it is not illustrated in the figures, the first controller 120 may obtain real time information between the maintenance device 200 and the each of the substrate process devices 20_1, 20_2, . . . , 20_{—}n which is used to control the transfer device 100.

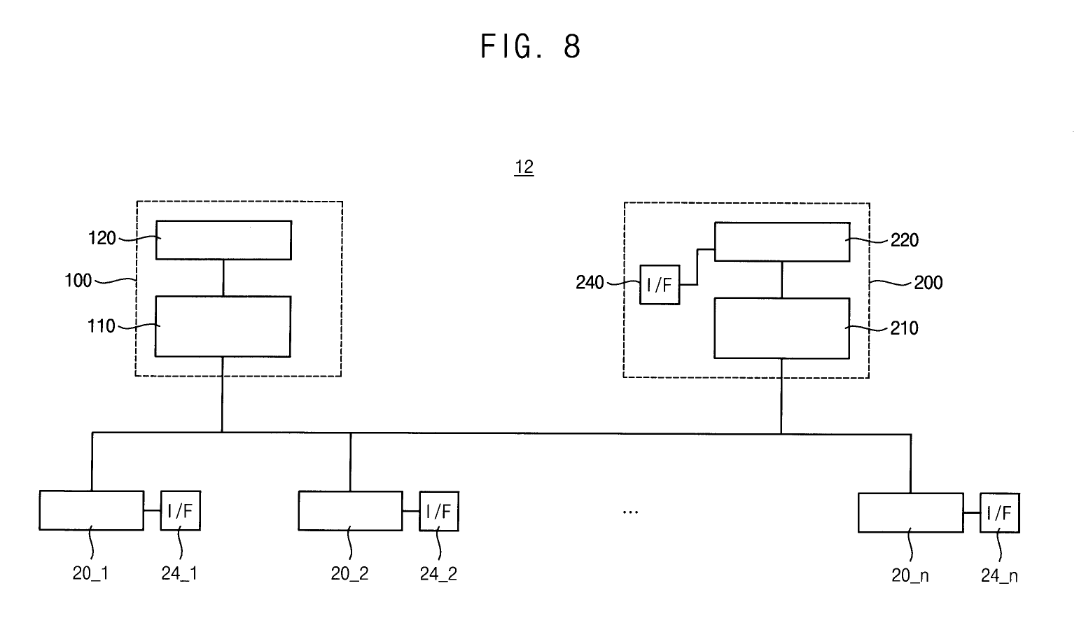

FIG. 8 is a block diagram illustrating a substrate processing system 12 in accordance with various aspects of exemplary embodiments. The substrate processing system 12 may be substantially the same as the substrate processing system 11, described with reference to FIG. 5, except that the substrate processing system 12 further includes an interface module for real time position information. Thus, like reference numerals refer to like elements, and detailed descriptions thereon are omitted herein.

Referring to FIG. 8, a substrate processing system 12 may include a plurality of substrate process devices 20_1, 20_2, . . . , 20_{—}n, at least one transfer device 100 configured to transfer a substrate between the substrate process devices 20_1, 20_2, . . . , 20_{—}n, and at least one maintenance device 200 configured to perform maintenance for the substrate process devices 20_1, 20_2, . . . , 20_{—}n.

As illustrated in FIG. 1, the transfer device 100 may include an overhead hoist transport (OHT) 110 which travels along a first line 30 installed above substrate process devices 20 and 22. Transfer device 100 may also include a first controller 120 which controls the OHT 110. The maintenance device 200 may include a crane 210a, 210b which travels along a second line 40a, 40b installed above substrate process devices 20 and 22. Maintenance device 200 may also include a second controller 220 which controls the crane 210a, 210b.

A substrate processing system 12 may further include first interface modules 24_1, 24_2, . . . , 24_{—}n and a second interface module 240 for a communication module between the transfer device 100 and the maintenance device 200.

A first interface module interface modules 24_1, 24_2, . . . , 24_{—}n may receive real time information between the transfer device 100 and each of the substrate process devices 20_1, 20_2, . . . , 20_{—}n and communicate with an external module. A second interface module 240 may be connected to the second controller 220 and communicate with the first interface module. The second controller 220 may obtain real time information between the transfer device 100 and a substrate process device 20 or 22 through the first interface modules 24_1, 24_2, . . . , 24_{—}n and second interface modules 240 to control maintenance operations.

A first interface module may be installed in each of the substrate process devices 20_1, 20_2, . . . , 20_{—}n. Alternatively, a first interface module 24 may be installed in the OHT 110 of the transfer device 100. A first interface module 24 may receive and transmit an optical signal between the OHT 110 of the transfer device 100 and a substrate process device 20_1, 20_2, . . . , 20_{—}n.

As illustrated in FIG. 6, the transfer device 100 may include a first optical communication interface 112A installed in the OHT 110 and each substrate process device 20 may include a second optical communication interface 112B.

First interface modules 24_1, 24_2, . . . , 24_{—}n may be connected to the first and second optical communication interfaces 112A and 112B to receive signals between the first and second optical communication interfaces 112A and 112B. Accordingly, a first interface module 24_1, 24_2, . . . , 24_{—}n may receive and process an optical signal representing real time information between the OHT 110 of the transfer device 100 and the substrate process device 20, and transmit the processed optical signal. A second interface module 240 may receive the processed optical signal from the first interface modules 24_1, 24_2, . . . , 24_{—}n and provide the processed optical signal to the second controller 220.

As illustrated in FIG. 8, for example, when the OHT 110 of the transfer device 100 is transferring a substrate to a first substrate process device 20_1, a busy signal may be transmitted between the first and second optical communication interfaces 112A and 112B. A first interface module 24_1 may obtain the busy signal between the first and second optical communication interfaces 112A and 112B and transmit the busy signal to the second interface module 240.

Then, the second controller 220 may obtain real time information between the transfer device 100 and each of the substrate process devices 20_1, 20_2, . . . , 20_{—}n and control the maintenance device 200. Alternatively, although it is not illustrated in the figures, the first controller 120 may obtain real time information between the maintenance device 200 and the each of the substrate process devices 20_1, 20_2, . . . , 20_{—}n which may be used to control the transfer device 100.

The foregoing is illustrative of aspects of exemplary embodiments and is not to be construed as limiting thereof. Although a few exemplary embodiments have been described, those skilled in the art will readily appreciate that many modifications are possible in exemplary embodiments without materially departing from the novel teachings and advantages of the exemplary embodiments. Accordingly, all such modifications are intended to be included within the scope of exemplary embodiments as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A substrate processing system, comprising:
a transfer device configured to transfer a substrate between a plurality of substrate processors, the transfer device comprising:
a first controller configured to control the transfer device, and
a first communication module connected to the first controller; and
a maintenance device configured to perform maintenance for the substrate processors, the maintenance device comprising:
a second controller configured to control the maintenance device, and
a second communication module connected to the second controller,
wherein the first controller is configured to control the transfer device using information about the maintenance device obtained from the first and second communication modules, and the second controller is configured to control the maintenance device using information about the transfer device obtained from the first and second communication modules.

2. The substrate processing system of claim 1, wherein the transfer device further comprises an overhead hoist transport (OHT).

3. The substrate processing system of claim 1, wherein the maintenance device further comprises a crane for maintenance or setup for the substrate processors.

4. The substrate processing system of claim 1, wherein the transfer device travels along a first line and the maintenance device travels along a second line independent of the first line.

5. The substrate processing system of claim 4, wherein the first line and the second line are arranged adjacent to each other.

6. The substrate processing system of claim 1, further comprising:
a first interface module configured to receive real time information between the transfer device and at least one of the substrate processors; and
a second interface module connected to the second controller which communicates with the first interface module,
wherein the second controller obtains real time information between the transfer device and at least one of the substrate processors through the first and second interface modules to control the maintenance operation.

7. The substrate processing system of claim 6, wherein the first interface module is installed in each of the substrate processors.

8. The substrate processing system of claim 6, wherein the first interface module receives and transmits an optical signal between the transfer device and at least one of the substrate processors.

9. The substrate processing system of claim 8, wherein the transfer device further comprises a first optical communication interface, each of the substrate processors comprises a second optical communication interface, and the first and second optical communication interfaces receive and transmit an optical signal as a control signal between the transfer device and each of the substrate processors.

10. The substrate processing system of claim 1, wherein the substrate processing system performs a photolithography process using the substrate processors.

11. A method of controlling a substrate processing system, the substrate processing system comprising a transfer device configured to transfer a substrate between a plurality of substrate processors and a maintenance device configured to perform maintenance for the substrate processors, comprising:
connecting first and second communication modules to the transfer device and the maintenance device respectively;
obtaining information about at least one of the transfer device or the maintenance device from at least one of the first and second communication modules; and
controlling at least one of the transfer device or the maintenance device to avoid interference between the transfer device and the maintenance device based on the obtained information.

12. The method of claim 11, wherein controlling at least one of the transfer device or the maintenance device comprises
discontinuing an operation of the maintenance device on the substrate processor when the transfer device operates on the substrate processor, or discontinuing an operation of the transfer device on the substrate processor when the maintenance device operates on the substrate processor.

13. The method of claim 11, further wherein the obtaining comprises:
obtaining information between the transfer device and each of the substrate process devices.

14. The method of claim 13, wherein obtaining information between the transfer device and the substrate processors comprises receiving and transmitting an optical signal between the transfer device and the substrate processors using first and second optical communication interfaces.

15. The method of claim 11, wherein the substrate processing system performs a photolithography process using the substrate processors.

16. A substrate processing method comprising:
transferring a substrate between a plurality of substrate processors;
obtaining position information of at least one of a transfer device and a maintenance device using a first module connected to the transfer device and a second module connected to the maintenance device;
detecting an interference condition between the transfer device and the maintenance device using the obtained position information;
adjusting an operation of at least one of the transfer device and the maintenance device to avoid the interference in response to detecting an interference condition is detected; and
processing the substrate according to the adjusted operation.

17. The method of claim 16, wherein the position information is communicated between the first and second modules.

18. The method of claim 16, wherein the position information is obtained from at least one of the substrate processors.

19. The method of claim 16, wherein the transferring is performed by an overhead hoist transport (OHT).

20. The method of claim 16, wherein the adjusting further comprises modifying at least one of movement of the transfer device along a first line and movement of the maintenance device along a second line independent of the first line.
